(19) United States
(12) Patent Application Publication
(10) Pub. No.: US 2024/0418797 A1
(43) Pub. Date: Dec. 19, 2024

(54) Overhead power line monitoring method and sensors

(71) Applicants: David Skrovanek, Madison, WI (US); PI-COM Ingenieurbüro für Telekommunikation & Nachrichtentechnik e.K., Radeberg (DE)

(72) Inventor: Christian Großer, Radeberg (DE)

(73) Assignees: David Skrovanek, Madison, WI (US); PI-COM Ingenieurbüro für Telekommunikation & Nachrichtentechnik e.K., Radeberg (DE)

(21) Appl. No.: 18/741,931

(22) Filed: Jun. 13, 2024

(30) Foreign Application Priority Data
Jun. 14, 2023 (DE) 10 2023 115 545.8

(51) Int. Cl. G01R 31/58; G01L 1/24; G01P 5/06; G01P 5/26

(52) U.S. Cl. CPC G01R 31/58; G01P 5/065; G01P 5/26; G01L 1/243

(57) ABSTRACT

An overhead line monitoring method includes generating evaluable measured variables on the basis of wind speeds at a plurality of measurement points. Therein, wind energy at a measurement point is converted into a rotational movement of a rotor of a measuring transducer, and the rotational movement is converted into a periodic, local deformation of at least one fiber optic cable running parallel to the overhead line at the measurement point. The method further includes calculating the wind speeds at the measurement points by evaluating periodic changes in signal attenuation, caused by the deformation, in the fiber optic cable, and assessing the operating state of the overhead line on the basis of the wind speeds.

### CROSS-REFERENCE TO RELATED APPLICATION

This application claims the benefit of German Patent Application DE 10 2023 115 545.8, filed on Jun. 14, 2023, the content of which is incorporated by reference in its entirety.

### BACKGROUND

The disclosure relates to an overhead line monitoring method in which an operating state of an overhead line is characterized through measurements, in order to keep the operating state of the overhead line in a predefinable permissible range depending on weather-related influences by regulating an energy supply into the overhead line, and at the same time to maximize the energy utilization of the overhead line within the permissible range of the operating state. The disclosure also relates to a measuring transducer for generating an evaluable measured variable on the basis of a wind speed.

Applying dynamic line rating (DLR) enables grid operators to dynamically adapt the rated power of high-voltage overhead lines by recording and analysing environmental weather data such as outside temperature and wind speed, and to use them well above their static transport limits.

The current challenges may be summarized as follows here:
significantly greater power transport using existing installations
more frequent and more severe one-off weather-related stress caused by temperature and wind
existing installations are usually 40 years old or more
linear and large-scale infrastructure, in particular for 380 kV dual-system and multi-system lines
linear infrastructure is located in visible and publicly accessible space
constant changes of intersections in public space.

This justifies the need to record conductor cable conditions and weather-related conditions. For this purpose, use has been made to date of electronic systems that have to rely on a stable energy supply and ensure protected data transmission over public grids.

Determining wind conditions, in combination with measuring the temperature, knowledge of the current conductor cable current I_{Ls} and taking into consideration the time-dependent and day-dependent solar elevation H_{S}, makes it possible to calculate the possible current increase and the conductor cable temperature.

These parameters may be used to calculate the various sources of heat absorption and output on the conductor cable (convection P_{C}, Joule heat P_{J}, solar radiation P_{S} and thermal radiation PR), from which it is ultimately possible to derive the conductor cable temperature ϑ_{HL} and thus the current carrying capacity. The effective wind speed plays an important role here, since exact knowledge of cooling convection has a much greater influence on DLR than moderate temperature changes. However, this is much more difficult to capture, as volatility may be much higher and individual measurements reveal little with regard to the overall length.

Established measuring systems record individual parameters or several of these parameters directly and indirectly. They may be divided roughly into the following categories:
statistical methods: Use of historical weather data
time-continuous measuring methods in or on the line: Weather stations, LIDAR-based measuring methods, and measuring systems on main conductors

Apart from the statistical methods, these DLR systems require an external power supply. Installing these systems requires considerable effort, which at times leads to the circuits being temporarily shut down during installation and maintenance. Since these devices generally transmit their data over public telecommunications networks, there are also additional attack vectors for cyber attacks for the grid operator. On the other hand, weather models lack real verification of the environmental variables, which remain absolutely necessary. To avoid these problems, it is possible to use fiber optic technologies and integrate them into the existing fiber optic infrastructure of transmission grids.

WO 2021/207093 A1 proposes an anemometer that is attached directly to a supply mast and that, through its rotation, generates mechanical oscillations/vibrations that are in turn transmitted to the mast and thus also indirectly to the fiber optic cable and then sensed by a DFOS (Distributed Fiber Optic Sensing) technology. Since a vibration of the mast and of the fiber optic cable may ultimately be brought about by a wide variety of causes, not least by the wind itself, such a wind speed measurement turns out to be very inaccurate.

### SUMMARY

The disclosure is based on the object of providing an overhead line monitoring method and a measuring transducer that make it possible to characterize the operating state of an overhead line through measurements, in order to keep the operating state of the overhead line in a predefinable permissible range depending on weather-related influences by regulating an energy supply into the overhead line, and at the same time to maximize the energy utilization of the overhead line within the permissible range of the operating state. One or more of the following objectives should be achieved here, as far as possible: highest possible transmission capacity of the circuits, low safety margins or safety reserves, high operational safety and public safety, continuous, and if possible spatially resolved assessment, low electrical power requirement for the measuring technology, permanent accessibility of the monitoring technology, ability to verify the measurement results, low installation effort.

To achieve this object, what is proposed is an overhead line monitoring method in which an operating state of an overhead line is characterized through measurements, in order to keep the operating state of the overhead line in a predefinable permissible range depending on weather-related influences by regulating an energy supply into the overhead line, and at the same time to maximize the energy utilization of the overhead line within the permissible range of the operating state.

The first step here is to generate evaluable measured variables on the basis of wind speeds vᵢ at a plurality n of measurement points i=1 . . . n along an overhead line, in particular at installation locations of pylons.

To generate the evaluable measured variables, wind energy at a measurement point i is converted into a rotational movement of a rotor of a measuring transducer, wherein an angular velocity ωᵢ of the rotational movement is proportional to the wind speed vᵢ.

The wind energy is converted here into a rotational movement, in particular by a rotor mounted so as to be able to rotate, such as for example a half-cup anemometer, an impeller anemometer, a wind turbine or a comparable suitable device.

The rotational movement is converted into a periodic, local deformation of at least one fiber optic cable running parallel to the overhead line at the measurement point i, wherein a deformation frequency fᵢ of the deformation is proportional to the angular velocity ωᵢ of the rotational movement.

The fiber optic cable is in particular an optical fiber in an optical ground wire (OPGW). As an alternative, the deformation of a fiber optic cable may take place in an optical phase conductor (OPPC). Both OPWG and (albeit less frequently) OPPC have already been laid on most overhead lines for information transmission purposes, and so it is advantageously possible to use existing infrastructure to perform the method.

The periodic, local deformation of the at least one fiber optic cable is a mechanical influence on the fiber optic cable and, as such, generates attenuation of the signals guided through the fiber optic cable. In this case, pressure-induced bending losses lead to transmission changes in the fiber optic cable, that is to say use is made of a fiber optic effect in which it is possible to observe a significant increase, able to be locally restricted, in attenuation caused by bending of a fiber optic cable. The generated periodic change in attenuation is preferably detected by way of an optical level measuring system consisting of a transmitter and a receiver. It is not necessary to use a Bragg grating to generate signals. On the contrary, the optical change in attenuation of an optical fiber caused by mechanical influences, which is easier to evaluate, is used to generate signals.

Following the generation of evaluable measured variables, the next step is to calculate the wind speeds vᵢ at the n measurement points by evaluating periodic changes in a signal attenuation, caused by the deformation, in the fiber optic cable using the proportionality factors between the wind speeds vᵢ and the angular velocities @; and between the angular velocities w; and the deformation frequencies fᵢ.

Finally, the operating state of the overhead line is assessed on the basis of the wind speeds vᵢ.

Preferably, one or more fiber optic cables are deformed at at least two, particularly preferably at at least three, very particularly preferably at at least four measurement points along an overhead line. Provision may be made for one or more fiber optic cables each to be deformed on a pylon, wherein the operating state of the overhead line is able to be assessed with greater accuracy the more measurement points along the overhead line are used. Preferably, one or more fiber optic cables are deformed along the entire transmission path. According to one particularly preferred embodiment, the wind speed is recorded every 1 to 4 km.

The conversion of the wind energy into a rotational movement preferably takes place in each case on the corner leg of a pylon on a jib. This reduces the influences on the mast structure caused by air turbulence or wind shading. Provision may in particular be made for the conversion of the wind energy into a rotational movement to take place more on a lower jib (for example level with the lower main conductor), since wind speeds on a pylon usually decrease towards the ground. This ensures that wind speeds in the lower range are more likely to be used when assessing the operating state of the overhead line, and the overhead lines tend to be cooled somewhat more by higher wind speeds.

Preferably, in parallel with the generation of evaluable measured variables depending on wind speeds, the outside temperature profile along the overhead line is also determined at a plurality of measurement points, preferably via distributed temperature sensing (DTS). The determined outside temperatures may be used when assessing the operating state of the overhead line in addition to the wind speeds in order to increase the accuracy of the method.

Provision may be made for example for one and the same fiber optic cable to be periodically locally deformed at at least two measurement points i, for example on different pylons.

Preferably, in this case, the wind speeds vᵢ are resolved according to the individual measurement points i based on the propagation time difference between the evaluated signals. The propagation time difference between the evaluated signals is preferably recorded here by way of an optical time domain reflectometer (OTDR).

This advantageously makes it possible to save on the optical fibers to be used.

According to one alternative embodiment, a first fiber optic cable is deformed at a first measurement point i₁ and a second fiber optic cable is deformed at a second measurement point i₂.

The amount of equipment involved is higher here, but the evaluation is simpler.

According to one preferred embodiment of the method, a speed reduction takes place when the rotational movement is converted into a periodic, local deformation of the fiber optic cable, as a result of which the mechanical loading on the respective optical fiber or on the respective fiber optic cable is greatly minimized.

Provision may be made here for a reduction ratio of at least 1:50, preferably at least 1:100, particularly preferably at least 1:140.

According to one preferred embodiment of the method, provision may be made to calculate the wind speeds vᵢ using the following formula:

$$\\ {V}_{w} = a + 2 π r \frac{Nb}{T}$$

This formula should be used in particular when a half-cup anemometer is used as rotor. Here, a is the initial speed (that is to say the minimum speed at which the anemometer begins to rotate), r is the radius of the rotor, N is the speed reduction ratio, T is the period of the measured signal, and b is the pressure coefficient between concave and convex hemispheres.

Provision may furthermore be made for the periodic change in the signal attenuation in the fiber optic cable to be detected by way of an optical level measuring system. An optical level measuring system consists here of an optical transmitter and a receiver and may be used to evaluate the signals in addition to detecting them. For this purpose, a fiber monitoring system is coupled to the respective measurement fiber (the respective fiber optic cable) via the optical cable terminal of the fiber optic cable installation in a station of the grid operator, for example a switching station or a substation. The monitoring system has a data interface for querying measured values.

The object is furthermore achieved by a measuring transducer for generating an evaluable measured variable on the basis of a wind speed, comprising a rotor able to be set into a rotational movement by the effect of wind energy and mounted in or on a housing so as to be able to rotate, a fiber guide arranged in or on the housing for a fiber optic cable, and a coupling member that is designed to convert a rotational movement of the rotor into a periodic, local deformation of a fiber optic cable running through the fiber guide.

The rotor is preferably here designed as a half-cup anemometer, alternative embodiments such as an impeller anemometer, a wind turbine or a comparable suitable device being conceivable.

According to one preferred embodiment of the measuring transducer, the coupling member is connected to the fiber guide in which a fiber optic cable is guided through the housing. In this case, the coupling member comprises the two guide elements and an actuation element, wherein the guide elements are arranged on a first side and the actuation element is arranged on a second side, opposite the first side, of the fiber optic cable, and wherein the actuation element is able to be moved back and forth between a rest position and an active position and, in the active position, the actuation element and the guide elements interact in such a way as to deform the fiber optic cable.

Provision may be made for at least one additional guide element to be arranged on the second side of the fiber optic cable.

A guide element should be understood here to mean any technical means that is arranged in the vicinity of the course of the fiber optic cable through the housing such that the fiber optic cable is in contact with the guide element either permanently or at least in the event of a transverse force acting on the fiber optic cable. Such guide elements may be designed for example as pins, plates, grooves, bores, etc., this list being purely exemplary and in no way limiting.

Provision may be made for there to be, in addition to the two known guide elements, at least one further guide element that is however not located on the same side as the previous guide elements, but rather on the opposite side on which the actuation element or at least a contact region of the actuation element that is able to be brought into contact with the fiber optic cable is also arranged. Increasing the number of guide elements and arranging them with relatively small distances between one another makes it possible to significantly increase the achievable attenuation.

If lateral pressure is exerted on the fiber optic cable—for example directly by the actuation element or by a movement of one or more guide elements caused by the actuation element-then the fiber optic cable is pressed against all guide elements even in the event of a small elastic deformation, such that lateral pressure is exerted on the fiber optic cable at each individual support point formed by a guide element. If the actuation element acts directly on the fiber optic cable, then transverse pressure-induced attenuation is of course also generated there. The attenuations induced thereby at all contact points add together. Minimal bending of the fiber optic cable fiber is thus sufficient to generate a detectable signal. The fiber optic cable fiber is thereby protected and keeps its original mechanical elasticity even in the event of a large number of actuation procedures.

According to one embodiment, provision may be made for at least three guide elements to be arranged along the fiber optic cable, in each case alternately on one of the two sides of the fiber optic cable. Of course, this number may also be increased further, and may also be doubled through a symmetrical arrangement of the guide elements relative to the actuation element.

According to one preferred embodiment of the measuring transducer, the coupling member has an eccentric that is designed to convert the rotational movement of the rotor into a linear movement of the actuation element.

This advantageously makes it possible to generate a periodic deformation of a fiber optic cable, wherein the deformation frequency fᵢ of the deformation is proportional to the angular velocity ωᵢ of the rotational movement and thus indirectly proportional to the wind energy at the respective measurement point.

As an alternative, provision may be made here for the eccentric itself to act as actuation element and thus to act directly on the fiber optic cable.

According to one preferred embodiment, the coupling member has a speed reduction arrangement. In other words, the measuring transducer may have a reduction gear between the rotor and the eccentric.

Such a speed reduction arrangement may be designed for example as a cogwheel drive, timing belt drive, chain gear or belt drive. In one preferred embodiment, the speed reduction arrangement is designed as a planetary gear.

The speed reduction arrangement reduces the speed of the half-cup anemometer. The torque used to influence the optical fiber is thus increased indirectly proportionally. It is thereby possible to reduce feedback and thus distortion of the speed of the half-cup anemometer to a negligible value. In the event of mechanical influencing of the optical fiber caused by direct coupling without a reduction of the resulting interacting force between the optical fiber and the influencing mechanism, which allows a direct response to the torque of the half-cup anemometer, the speed and thus the measured wind speed would otherwise be distorted. Using a speed reduction arrangement therefore makes it possible to determine the wind speed with a higher accuracy.

In one exemplary embodiment, the eccentric has an eccentric rotor that is connected, at a first end via a pinion, to the rotor of the measuring transducer or to the planetary gear and that rotates eccentrically about an axis of rotation. The rotor is preferably operatively connected to an impact element that may be formed for example as a plate with a through-recess in which the eccentric rotor is arranged. The rotation of the eccentric rotor sets the impact element, which in turn comprises the actuation element or is connected to the actuation element, into a linear movement that is arranged perpendicular to the axis of rotation.

Provision may also be made for the fiber optic cable in the housing to be guided in a loop or ribbon shape such that at least two sections of the fiber optic cable are passed through between guide elements and the actuation element.

The number of loops or ribbons in this case, like the number of guide elements, may be used to individually code individual measuring transducers, because this also makes it possible to set the achieved degree of attenuation. In a fiber optic network comprising at least two measuring transducers, of which, at least in one measuring transducer, two or more sections of the fiber optic cable are passed through between guide elements and actuation element, it is thus easy to determine which measuring transducer generated a detected signal. If more than two measuring transducers are present in the network, a different number of sections of the fiber optic cable may advantageously be guided through between guide elements and actuation element in each measuring transducer.

The operating principle of the measuring transducer is based on utilizing a fiber optic effect in which it is possible to observe a significant increase in attenuation, able to be locally restricted, caused by bending of a glass fiber, and is achieved using only fiber optic components, without the use of auxiliary electrical energy.

The measured values are transmitted over the optical ground wire (OPGW) of the transmission line, the transmission therefore not being dependent on the use of public telecommunications networks. The entire measuring technique is easily able to be retrofitted to existing transmission lines. The monitoring devices are advantageously installed at the endpoints of the line, for example in the substations or switching stations of the grid operators.

### BRIEF DESCRIPTION OF THE DRAWINGS

The invention is explained in more detail below with reference to exemplary embodiments and associated drawings. In the figures:

FIG. 1: shows a perspective view of an exemplary measuring transducer;

FIG. 2: shows a schematic side view of an exemplary measuring transducer;

FIG. 3: shows a longitudinal section through the measuring transducer in the plane A: A of FIG. 2;

FIG. 4: shows a perspective view into the inside of an exemplary measuring transducer;

FIG. 5: shows a cross section through the measuring transducer in the plane B: B of FIG. 2;

FIG. 6: shows a schematic arrangement of a plurality of measuring transducers on fiber loops of different fiber optic cables, at different measurement points along an overhead line;

FIG. 7: shows a schematic arrangement of a plurality of measuring transducers on fiber loops of the same fiber optic cable, at different measurement points along an overhead line;

FIG. 8: shows a schematic sketch for clarifying the evaluation principle of a plurality of measuring transducers arranged as in FIG. 7; and

FIG. 9: shows a possible arrangement of an exemplary measuring transducer on a pylon.

### DETAILED DESCRIPTION

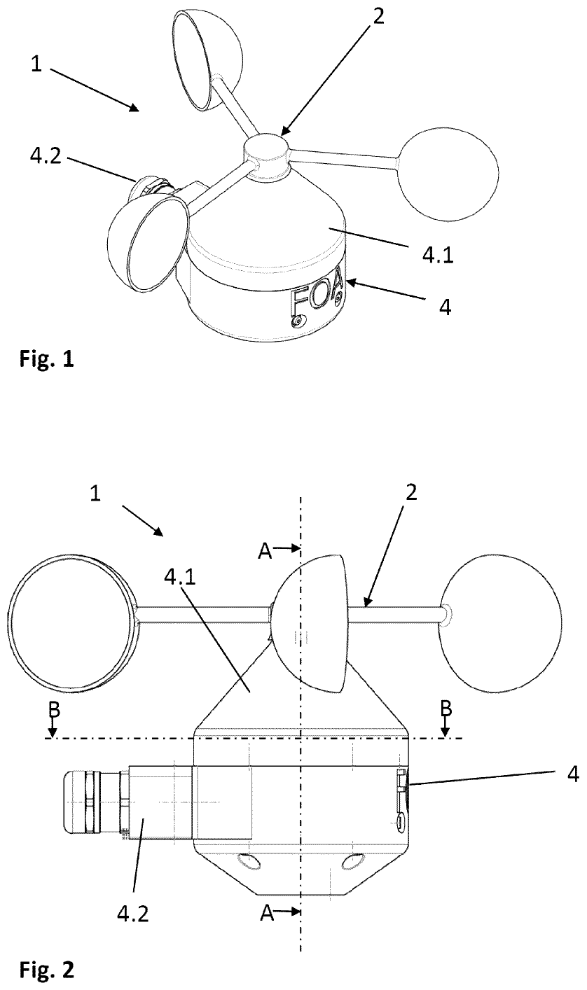

FIG. 1 shows a perspective view of a measuring transducer 1, while FIG. 2 shows the measuring transducer 1 in a schematic side view.

The measuring transducer 1 has a housing 4 and a rotor 2 mounted in or on the housing 4 so as to be able to rotate. In the illustrated exemplary embodiment, the rotor 2 is designed as a half-cup anemometer. The housing 4 is able to be closed off by a cover 4.1.

The housing 4 furthermore has a connection opening 4.2 through which the fiber optic cable is guided both into the housing 4 and out of the housing 4.

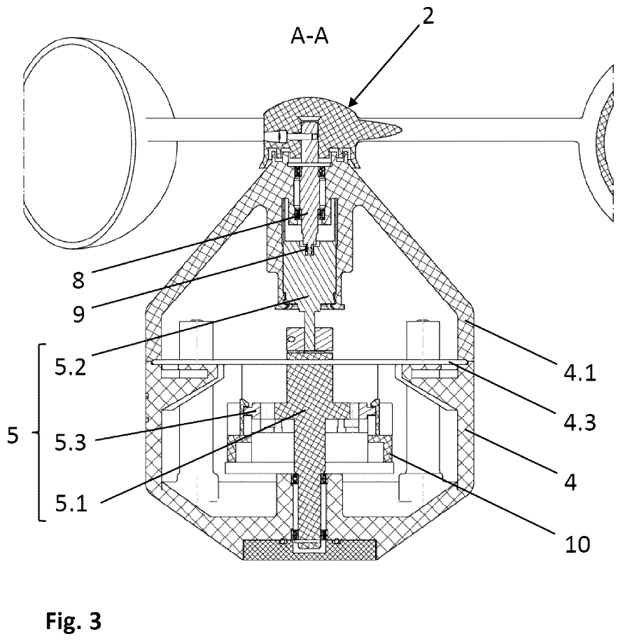

FIG. 3 illustrates a measuring transducer 1 in longitudinal section in the plane A: A of FIG. 2. The rotor 2 is mounted on the cover 4.1 of the housing 4 so as to be able to rotate. The cover 4.1 and the housing 4 are sealed off from one another by an O-ring 4.3.

The rotor 2 is able to be set into a rotational movement by wind energy, and drives a pinion shaft 8. The pinion shaft 8 is connected to a planetary gear 5.2 of a coupling member 5 via a pinion 9. The planetary gear 5.2 in turn acts on an eccentric 5.1 and transmits the rotational movement of the pinion shaft 8 to the eccentric 5.1. In this case, the planetary gear 5.2 carries out a speed reduction.

The eccentric 5.1 and the planetary gear 5.2 are part of a coupling member 5, which is designed to convert the rotational movement of the rotor 2 into a linear movement of an actuation element (not shown in FIG. 3).

In the illustrated exemplary embodiment, an impact plate 5.3 is likewise designed as part of the coupling member 5. The impact plate 5.3 is arranged in a plane perpendicular to the axis of rotation of the eccentric 5.1 and has an aperture within which the control disc of the eccentric 5.1 is arranged, wherein the centre of the control disc lies outside the axis of rotation of the eccentric 5.1.

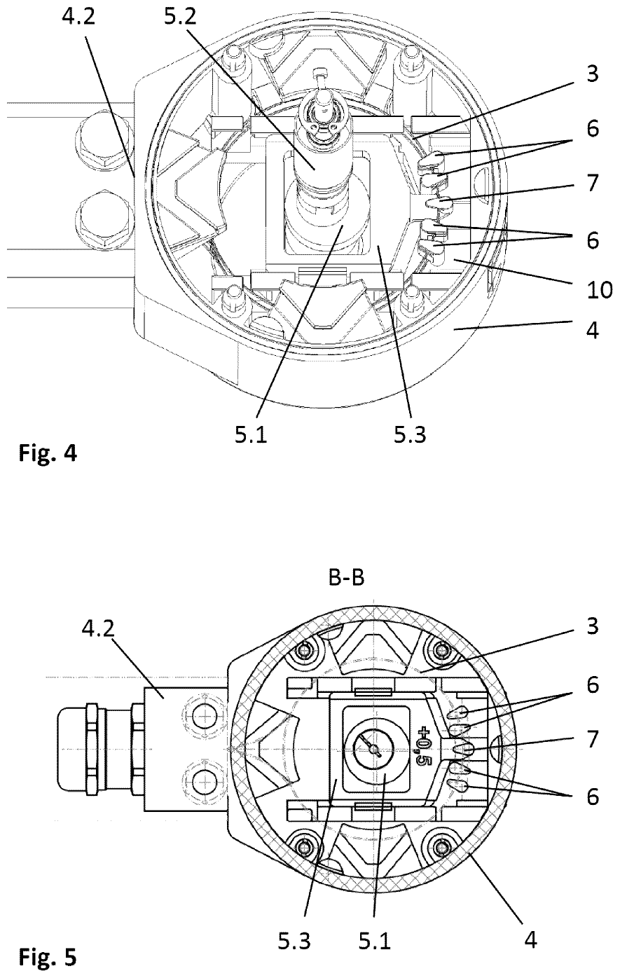

The interaction between the eccentric 5.1 and the impact plate 5.3 in shown in detail in FIG. 4, which shows a perspective view into the inside of a measuring transducer 1. The aperture in the impact plate 5.3 corresponds here substantially to the radius of the control disc of the eccentric 5.1, such that the impact plate 5.3 is set into a linear movement by the rotational movement of the eccentric 5.1. The impact plate 5.3 is guided here in the fiber plate 10. An actuation element 7 is connected to the impact plate 5.3.

A fiber optic cable 3 is guided in a loop on the fiber plate 10 such that a plurality of sections of the fiber optic cable 3 are guided through between guide elements 6 formed on the fiber plate 10 and the actuation element 7 arranged on the impact plate 5.3, such that the actuation element 7 and each guide element 6 act simultaneously at multiple points on the fiber optic cable 3. In this case, the actuation element 7 acts on the fiber optic cable 3 from the side thereof remote from the impact plate 5.3. The two guide elements 6 closest to the two sides of the actuation element 7 are arranged such that they act on the fiber optic cable 3 from the side thereof facing the impact plate 5.3, while the two external guide elements 6, which are at the greatest distance from the actuation element 7, in turn act on the fiber optic cable 3 from the side thereof remote from the impact plate 5.3.

The actuation element 7 is able to be moved from a rest position to an active position by the linear movement of the impact plate 5.3, wherein the actuation element 7, in its active position, and the guide elements 6 interact such that the fiber optic cable 3 is deformed and the signals in the fiber optic cable 3 are thus attenuated.

The fiber optic cable 3 is guided into the housing 4 and out of the housing 4 through the connection opening 4.2. The signal attenuation is evaluated outside the measuring transducer 1, preferably via coupling of a fiber monitoring system to the fiber optic cable 3 via the optical cable terminal of the fiber optic cable installation in the station of the grid operator.

FIG. 5 shows a cross section through the measuring transducer 1 in the plane B: B of FIG. 2. In addition to the details described in FIG. 4, it may be seen that the guide elements 6 are arranged symmetrically relative to the actuation element 7.

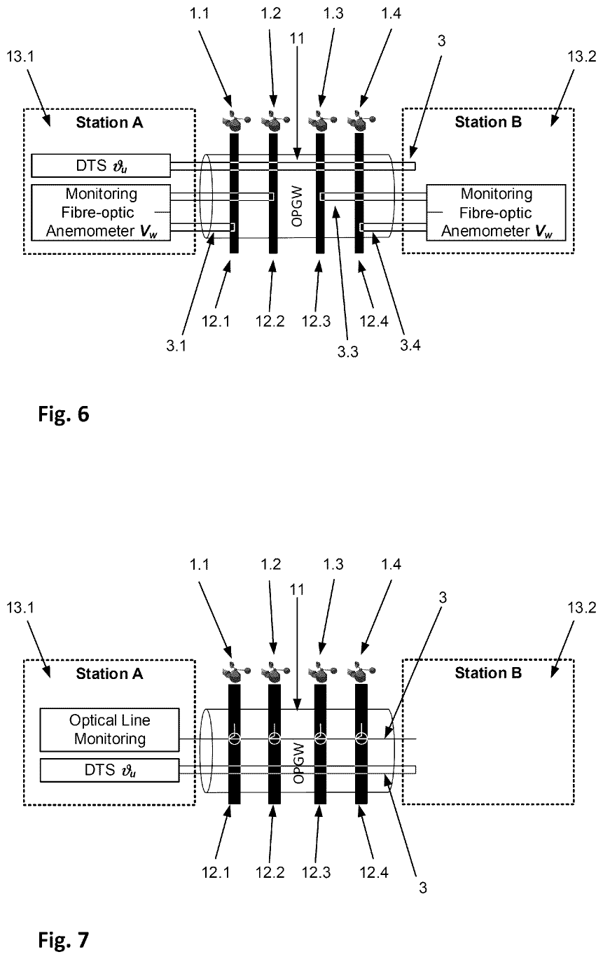

A possible circuit arrangement of a plurality of measuring transducers 1 is illustrated schematically in each of FIGS. 6 and 7.

FIG. 6 here shows an arrangement of a plurality of measuring transducers 1 at different measurement points along an overhead line (level measuring principle), wherein each measuring transducer is coupled to a fiber loop of another fiber optic cable.

FIG. 7, on the other hand, shows an arrangement of a plurality of measuring transducers 1 at different measurement points along an overhead line, wherein all of the measuring transducers are coupled to fiber loops of the same fiber optic cable.

In the embodiment according to FIG. 6, a plurality of fiber optic cables of an optical ground wire (OPGW) 11 are connected to a respective measuring transducer. The measuring transducers 1.1, 1.2, 1.3, 1.4 are arranged at different measurement points, which are preferably located on a respective pylon 12.1, 12.2, 12.3, 12.4. For this purpose, two fiber optic cables are coupled to one other at each measurement point to form a fiber loop 3.1, 3.2, 3.3, 3.4, which is guided by a measuring transducer 1.1, 1.2, 1.3, 1.4 and is locally deformed therein.

On a first pylon 12.1, a first measuring transducer 1.1 is connected to a first fiber optic cable 3.1. On a second pylon 12.2, a second measuring transducer 1.2 is connected to a second fiber optic cable 3.2. On a third pylon 12.3, a third measuring transducer 1.3 is connected to a third fiber optic cable 3.3. On a fourth pylon 12.4, a fourth measuring transducer 1.4 is connected to a fourth fiber optic cable 3.4. Further measuring transducers may be connected to further fiber optic cables.

The periodic changes in attenuation in the respective fiber optic cables 3.1, 3.2, 3.3, 3.4 generated by the measuring transducers 1.1, 1.2, 1.3, 1.4 are detected and evaluated by way of an optical level measuring system (consisting of optical transmitter and receiver). For this purpose, a fiber monitoring system is connected to the respective fiber optic cables 3.1, 3.2, 3.3, 3.4 via the optical cable terminal of the fiber optic cable installation in a station of the grid operator, for example a substation or an item of switchgear.

In the illustrated exemplary embodiments, the temperature is recorded along the OPGW 11 by way of distributed temperature sensing (DTS) in parallel both when the measuring transducers are coupled to different fiber optic cables (FIG. 6) and when all of the measuring transducers are coupled to the same fiber optic cable (FIG. 7). The temperature is recorded here on one or more further fiber optic cables 3.

With a length resolution in the sub-metre range, the DTS measurement enables a detailed reproduction of the temperature distribution along the line. This makes it possible to clearly define and assess individual regions of the line. Segments of the overhead line are considered in order to determine the temperature, which is relevant to weather-dependent overhead line operation. These segments may be individual spans, guy sections, fit lengths between the fiber optic cable sleeves or the entire length between the portals.

In the embodiment according to FIG. 7, a plurality of measuring transducers 1.1, 1.2, 1.3, 1.4 are arranged along a single fiber optic cable 3, preferably in each case at the installation points of the pylons 12.1, 12.2, 12.3, 12.4. The generated signal attenuations are evaluated in a first station 13.1 (substation or switchgear of the grid operator), wherein the propagation time difference between the evaluated signals is used to resolve the wind speeds vᵢ according to the individual measurement points i. The propagation time difference between the evaluated signals is preferably recorded here by way of an OTDR-based monitoring system.

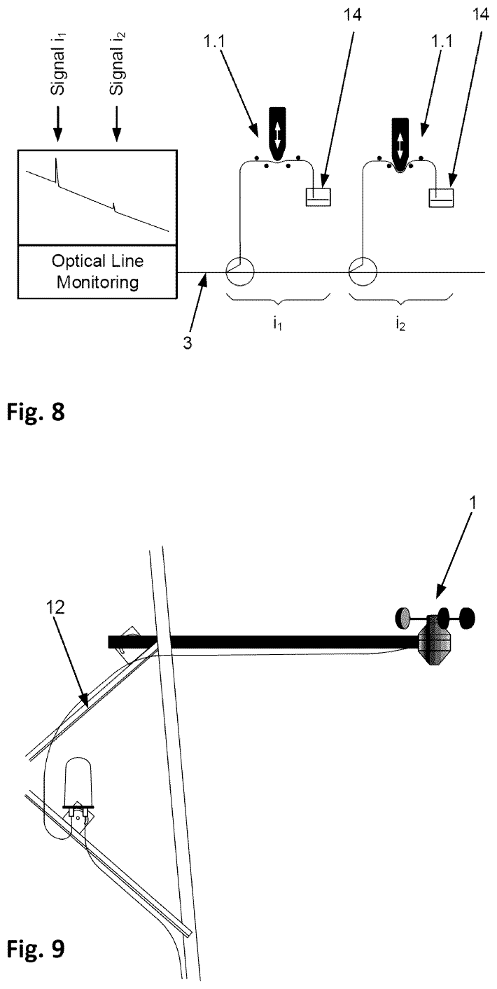

Details regarding the evaluation of the generated signal attenuations are illustrated in FIG. 8. This shows a schematic sketch to illustrate the evaluation principle of a plurality of measuring transducers 1 that are connected to the same fiber optic cable.

A first measuring transducer 1.1 is connected to the fiber optic cable 3 at a first measurement point i₁ and a second measuring transducer 1.2 is connected to the fiber optic cable 3 at a second measurement point i₂, in each case via a passive optical splitter 15.

Starting from the transmitter of an optical time domain reflectometer OTDR, an optical signal is output into a fiber optic cable 3. At a first measurement point i₁, the signal is guided, via a passive optical splitter 15, to a first measuring transducer 1.1. The signal passes through the first measuring transducer 1.1, is attenuated accordingly and reflected via a broadband reflector 14, whereupon it is received by the receiver of the OTDR as signal from the first measurement point i₁. At a second measurement point i₂, the signal is guided, via a passive optical splitter 15, to a second measuring transducer 1.2. The signal passes through the second measuring transducer 1.2, is attenuated accordingly and reflected via a broadband reflector 14, whereupon it is received by the receiver of the OTDR as signal from the second measurement point i₂. Determining the propagation time difference between the evaluated signals makes it possible to resolve the wind speeds vᵢ according to the individual measurement points i. The operating state of the overhead line is then assessed on the basis of the determined wind speeds vᵢ.

FIG. 9 shows a possible arrangement of a measuring transducer 1 on a pylon 12. The measuring transducer 1 is preferably installed here on the corner leg of the pylon 12 on a jib. This reduces the influences on the mast structure caused by air turbulence or wind shading. Provision is advantageously made for the installation to be carried out level with the lower main conductors.

### LIST OF REFERENCE SIGNS

1 Measuring transducer
1.1 First measuring transducer
1.2 Second measuring transducer
1.3 Third measuring transducer
1.4 Fourth measuring transducer
2 Rotor
3 Fiber optic cable
3.1 First fiber optic cable
3.2 Second fiber optic cable
3.3 Third fiber optic cable
3.4 Fourth fiber optic cable
4 Housing
   a. Cover
   b. Connection opening
   c. O-ring
5 Coupling member
5.1 Eccentric
5.2 Planetary gear
5.3 Impact plate
6 Guide elements
7 Actuation element
8 Pinion shaft
9 Pinion
10 Fiber plate
11 Optical ground wire
12 Pylon
12.1 First pylon
12.2 Second pylon
12.3 Third pylon
12.4 Fourth pylon
13.1 First station of the grid operator
13.2 Second station of the grid operator
14 Broadband reflector
15 Passive optical splitter
vᵢ Wind speed
ωᵢ Angular velocity of the rotational movement
fᵢ Deformation frequency of the deformation of a fiber optic cable
iₙ Measurement point
iₙ First measurement point
i₂ Second measurement point

What is claimed is:

1. A method for monitoring an overhead line in which an operating state of the overhead line is characterized through measurements, in order to keep the operating state of the overhead line in a permissible range depending on weather-related influences by regulating an energy supply into the overhead line, and to simultaneously maximize an energy utilization of the overhead line within the permissible range of the operating state, the method comprising:
generating evaluable measured variables based on wind speeds (vᵢ) at a plurality of measurement points (i=1 . . . n) along the overhead line, including converting wind energy at a measurement point (i) into a rotational movement of a rotor of a measuring transducer, wherein an angular velocity (ωᵢ) of the rotational movement is proportional to a wind speed (vᵢ), and
converting the rotational movement into a periodic, local deformation of at least one fiber optic cable (3) running parallel to the overhead line at the measurement point (i), wherein a deformation frequency (fᵢ) of the periodic, local deformation is proportional to the angular velocity (ωᵢ) of the rotational movement;
calculating the wind speeds (vᵢ) at the plurality of measurement points by evaluating periodic changes in a signal attenuation, caused by the periodic, local deformation, in the at least one fiber optic cable (3) using proportionality factors between the wind speeds (vᵢ) and the angular velocities (ωᵢ) and between the angular velocities (ωᵢ) and the deformation frequencies (fᵢ); and
assessing the operating state of the overhead line based on the wind speeds (vᵢ).

2. The method according to claim 1,
wherein exactly one fiber optic cable (3) is periodically locally deformed at at least two different ones of the plurality of measurement points (i).

3. The method according to claim 2,
wherein the wind speeds (vᵢ) are resolved according to individual ones of the plurality of measurement points (i) based on a propagation time difference between evaluated signals.

4. The method according to claim 1,
wherein a first fiber optic cable is deformed at a first measurement point (i₁) and a second fiber optic cable is deformed at a second measurement point (i₂).

5. The method according to claim 1,
wherein a speed reduction takes place when the rotational movement is converted into the periodic, local deformation of the at least one fiber optic cable.

6. The method according to claim 1,
wherein the periodic changes in the signal attenuation in the at least one fiber optic cable is detected by an optical level measuring system.

7. A measuring transducer for generating an evaluable measured variable based on a wind speed, comprising:
a rotor able to be set into a rotational movement by effect of wind energy and mounted in or on a housing so as to be able to rotate;
a fiber guide arranged in or on the housing for a fiber optic cable; and
a coupling member that is designed to convert a rotational movement of the rotor into a periodic, local deformation of a fiber optic cable running through the fiber guide.

8. The measuring transducer according to claim 7,
wherein the rotor is a half-cup anemometer.

9. The measuring transducer according to claim 7,
wherein the coupling member is connected to the fiber guide in which a fiber optic cable is guided through the housing and comprises two guide elements and an actuation element,
wherein the two guide elements are arranged on a first side and the actuation element is arranged on a second side, opposite the first side, of the fiber optic cable, and
wherein the actuation element is able to be moved back and forth between a rest position and an active position and, in the active position, the actuation element and the two guide elements interact in such a way as to deform the fiber optic cable.

10. The measuring transducer according to claim 9,
wherein the two guide elements are arranged symmetrically relative to the actuation element.

11. The measuring transducer according to claim 9,
wherein the coupling member has an eccentric that is designed to convert the rotational movement of the rotor into a linear movement of the actuation element.

12. The measuring transducer according to claim 11,
wherein the eccentric acts as actuation element.

13. The measuring transducer according to claim 7,
wherein the coupling member has a speed reduction arrangement.

14. The measuring transducer according to claim 13,
wherein the speed reduction arrangement is designed as a planetary gear.
